(19) United States
(12) Patent Application Publication
(10) Pub. No.: US 2026/0321311 A1
(43) Pub. Date: Oct. 15, 2026

(54) STORAGE MODULE, STORAGE ARRAY, STORAGE APPARATUS, AND PROCESSING-IN-MEMORY PROGRAMMING METHOD

(71) Applicant: PEKING UNIVERSITY, Beijing (CN)

(72) Inventors: Zongwei WANG, Beijing (CN); Yimao CAI, Beijing (CN); Jinshan LI, Beijing (CN)

(73) Assignee: PEKING UNIVERSITY, Beijing (CN)

(21) Appl. No.: 19/437,519

(22) Filed: Dec. 31, 2025

(30) Foreign Application Priority Data
Apr. 10, 2025 (CN) 202510449782.5

(51) Int. Cl. G11C 13/00

(52) U.S. Cl. CPC G11C 13/0061; G11C 13/0026; G11C 13/0028; G11C 13/0069

(57) ABSTRACT

A storage module is provided, which includes a storage unit and a processing-in-memory unit. The storage unit is configured to connect a word line, a bit line, and a source line, and perform data programming, data reading, or data deleting based on the word line, the bit line, and the source line in a storage mode; the processing-in-memory unit is connected to the storage unit and is configured to: connect a timing word line, a computing word line, and a computing source line; acquire stored data of the storage unit based on the bit line and the timing word line in a first phase of a processing-in-memory mode; and perform processing-in-memory based on the computing word line and the computing source line in a second phase of the processing-in-memory mode.

### CROSS-REFERENCE TO RELATED APPLICATIONS

The present application claims priority to Chinese Patent Application No. 202510449782.5, filed on Apr. 10, 2025, and entitled “Storage Module, Storage Array, Storage Apparatus, and Processing-in-Memory Programming Method”, the content of which is expressly incorporated herein by reference in its entirety.

### TECHNICAL FIELD

The present disclosure relates to the field of semiconductor storage and computing, particularly to a storage module, a storage array, a storage apparatus, and a processing-in-memory programming method.

### BACKGROUND

Processing-in-Memory (PIM) is a novel technique that breaks through the conventional computing architecture. The core concept of the PIM is to directly perform data processing inside a storage module instead of a mode in conventional computing in which data is transferred from a memory to a processor (such as a CPU/GPU) for computing. By eliminating the “storage wall” (i.e., delay and energy consumption due to data transfer), this technology can greatly improve the computational efficiency and energy efficiency ratio, and thus is especially useful for scenarios where massive data needs to be processed, such as artificial intelligence, big data analysis, etc.

### SUMMARY

In view of this, the present disclosure provides a storage module, a storage array, a storage apparatus, and a processing-in-memory programming method, which can not only have advantages of non-volatile, high on-off ratio, extremely low turn-on current, elimination of a DC path during the computing, and compensation for mismatch of the discharge transistor, but also effectively improve parallelism, linearity, and energy efficiency of the processing-in-memory.

In order to achieve the above purposes, in the first aspect of the present disclosure, a storage module is provided, which includes a storage unit and a processing-in-memory unit. The storage unit is configured to connect a word line, a bit line, and a source line, and perform data programming, data reading, or data deleting based on the word line, the bit line, and the source line in a storage mode. The processing-in-memory unit is connected to the storage unit and is configured to: connect a timing word line, a computing word line, and a computing source line; acquire stored data of the storage unit based on the bit line and the timing word line in a first phase of a processing-in-memory mode; and perform processing-in-memory based on the computing word line and the computing source line in a second phase of the processing-in-memory mode.

In some embodiments of the present disclosure, the storage unit includes a first transistor and a resistive random access memory, a gate of the first transistor is connected to the word line, a first electrode of the first transistor is connected to the source line, a second electrode of the first transistor is connected to a first terminal of the resistive random access memory, and a second terminal of the resistive random access memory is connected to the bit line.

In some embodiments of the present disclosure, the processing-in-memory unit includes a second transistor, a third transistor, a capacitor, and a fourth transistor; a gate of the second transistor is connected to the timing word line; a first electrode of the second transistor is connected to the storage unit; a second electrode of the second transistor, a gate of the third transistor, and a first electrode of the capacitor are connected to form a restoration node; a first electrode of the third transistor is connected to a second electrode of the capacitor and is connected to a ground voltage terminal; a second electrode of the third transistor is connected to a first electrode of the fourth transistor, a gate of the fourth transistor is connected to the computing word line, a second electrode of the fourth transistor is connected to the computing source line.

In the second aspect of the present disclosure, a storage array is provided, which includes a plurality of storage cells arranged in an array, each storage cell includes a plurality of storage modules arranged in rows in a first direction. Restoration nodes of the plurality of storage modules in each storage cell are connected to each other and connected to a shared capacitor. The shared capacitor is configured to acquire stored data of a target storage module in a corresponding storage cell in response to a processing-in-memory control instruction in the processing-in-memory mode.

In some embodiments of the present disclosure, the plurality of storage cells are arranged in columns in a second direction, the second direction intersects the first direction, at least one column of storage cells is a virtual column of storage cells, and each storage module in the virtual column of storage cells stores pre-stored calibration data.

In the third aspect of the present disclosure, a storage apparatus is provided, which includes: the storage array of any one of the above embodiments; a read/write control circuit, connected to each storage cell in the storage array through a bit line driver circuit, a word line driver circuit and a source line driver circuit, and configured to transmit a storage control instruction to the bit line driver circuit, the word line driver circuit and the source line driver circuit respectively in a storage mode, to select the target storage module to perform the data programming, the data reading, or the data deleting; a processing-in-memory control circuit, connected to each storage cell in the storage array through a timing word line driver circuit, a computing word line pulse generation and driver circuit, and a computing source line processing circuit, and configured to: transmit a first processing-in-memory control instruction to the timing word line driver circuit in the first phase of the processing-in-memory mode, to acquire stored data of a plurality of target storage modules; and transmit a second processing-in-memory control instruction to the computing word line pulse generation and driver circuit and the computing source line processing circuit in the second phase of the processing-in-memory mode, to perform the processing-in-memory on the stored data of the plurality of target storage modules.

In some embodiments of the present disclosure, the storage apparatus further includes: a delay circuit, connected to the bit line driver circuit and the timing word line driver circuit, and configured to control charging time of the shared capacitor in the processing-in-memory mode.

In some embodiments of the present disclosure, the storage apparatus further includes: a computing post-processing circuit, connected to the computing source line processing circuit, and configured to perform post-processing on an operation structure of the processing-in-memory in the processing-in-memory mode and output a post-processing result.

In the fourth aspect of the present disclosure, a processing-in-memory programming method is provided, applied to the storage apparatus of any one of the above embodiments, the programming method includes:
selecting a plurality of target storage modules in a first target row from the storage array as a to-be-programmed group;
in a storage mode, performing first data programming on each of the plurality of target storage modules in the to-be-programmed group through the bit line driver circuit, the word line driver circuit, and the source line driver circuit;
in a first phase of a processing-in-memory mode, restoring stored data of each of the plurality of target storage modules in the to-be-programmed group to a corresponding shared capacitor of each target storage module through the bit line driver circuit and the timing word line driver circuit;
in a second phase of the processing-in-memory mode, controlling discharge of the corresponding shared capacitor of each target storage module through the computing word line pulse generation and driver circuit and the computing source line processing circuit, and detecting whether a discharge current of the corresponding shared capacitor of each target storage module satisfies a preset condition;
in response to the discharge current of the corresponding shared capacitor of each target storage module satisfying the preset condition, selecting a plurality of target storage modules in a second target row from the storage array as a to-be-programmed group; or
in response to that a discharge current of a corresponding shared capacitor of a target storage module in the plurality of target storage modules does not satisfy the preset condition, performing second data programming on each target storage module in the to-be-programmed group in the storage mode, and restoring stored data of each target storage module in the to-be-programmed group to a corresponding shared capacitor of each target storage module in the processing-in-memory mode, to redetect whether the discharge current of the corresponding shared capacitor of each target storage module satisfies the preset condition.

In some embodiments of the present disclosure, a programming precision of the second data programming is higher than that of the first data programming.

The present disclosure may/at least have the following advantages.

In the embodiments of the present disclosure, the storage module includes a storage unit and a processing-in-memory unit, the storage unit is configured to connect the word line, the bit line and the source line, so that in the storage mode, the data programming, the data reading or data deleting can be performed based on the word line, the bit line and the source line. The processing-in-memory unit is configured to connect the storage unit, the timing word line, the computing word line and the computing source line, so that the stored data of the storage unit can be obtained based on the bit line and timing word line in the first phase of the processing-in-memory mode, and the processing-in-memory can be performed based on the computing word line and the computing source line in the second phase of the processing-in-memory mode. Through the embodiments of the present disclosure, it is easy to decouple the operating paths of the storage module in the storage mode and the processing-in-memory mode, which is convenient to effectively improve the parallelism, linearity, and energy efficiency of the processing-in-memory while ensuring that the storage module has advantages of non-volatile, high on-off ratio, extremely low turn-on current, DC path elimination in the computing process, and compensation for discharge transistor mismatch.

The details of one or more embodiments of the present disclosure are presented in the following figures and descriptions. Other features, purposes, and advantages of the present disclosure will become obvious from the specification, the figures, and the claims.

### BRIEF DESCRIPTION OF THE DRAWINGS

In order to describe the technical solution in the embodiments of the present disclosure or the conventional technologies more clearly, the accompanying drawings required for describing the embodiments or the conventional technologies are briefly introduced below. Obviously, the accompanying drawings described below show merely some embodiments of the present disclosure, and those skilled in the art may still obtain other drawings from these accompanying drawings without any creative efforts.

FIG. 1 is a schematic principle diagram of some processing-in-memory circuits according to some embodiments.

FIG. 2 is a schematic structure diagram of a storage module according to some embodiments.

FIG. 3 is a schematic diagram of an equivalent circuit of a storage module according to some embodiments.

FIG. 4 is a schematic diagram of an operating principle of a storage module in a storage mode according to some embodiments.

FIG. 5 is a schematic diagram of an operating principle of a storage module in a first phase of a processing-in-memory mode according to some embodiments.

FIG. 6 is a waveform diagram of a voltage change of a storage module in a first phase of a processing-in-memory mode according to some embodiments.

FIG. 7 is a schematic diagram of an operating principle of a storage module in a second phase of a processing-in-memory mode according to some embodiments.

FIG. 8 is a waveform diagram of a current change of a storage module in a second phase of a processing-in-memory mode according to some embodiments.

FIG. 9 is a schematic structure diagram of a storage array according to some embodiments.

FIG. 10 is a schematic structure diagram of a storage apparatus according to some embodiments.

FIG. 11 is a schematic diagram of an operating principle of a storage apparatus in a storage mode according to some embodiments.

FIG. 12 is a schematic diagram of an operating principle of a storage apparatus in a first phase of a processing-in-memory mode according to some embodiments.

FIG. 13 is a schematic diagram of an operating principle of a storage apparatus in a second phase of a processing-in-memory mode according to some embodiments.

FIG. 14 is a flow chart showing a processing-in-memory programming method according to some embodiments.

### Reference Signs

HRC, storage module; 1, storage unit; 2, processing-in-memory unit; WL, word line; BL, bit line; SL, source line; TWL, timing word line; CWL, computing word line; CSL, computing source line; N₀, first transistor; R, resistive random access memory; N₁, second transistor; N₂, third transistor; N₃, fourth transistor; C, capacitor; 3, read/write control circuit; 31, bit line driver circuit; 32, word line driver circuit and source line driver circuit; 33, delay circuit; 4, processing-in-memory control circuit; 41, timing word line driver circuit; 42, computing word line pulse generation and driver circuit; 43, computing source line processing circuit; 44, computing post-processing circuit.

### DETAILED DESCRIPTION

For ease of understanding of the present disclosure, the present disclosure will be described more comprehensively with reference to related accompanying drawings. Some embodiments of the present disclosure are provided in the accompanying drawings. However, the present disclosure may be implemented in many different forms, and is not limited to the embodiments described herein. Rather, these embodiments are provided to make the disclosure more thorough and comprehensive.

Unless otherwise defined, all the technical and scientific terms used in this article have the same meanings as those commonly understood by technicians belonging to the technical field of the present disclosure. The terms used in the description of the present disclosure are merely to describe specific embodiments and are not intended to limit the present disclosure.

It should be appreciated that, although the terms first, second, third, and the like may be utilized to describe various elements, components, regions, layers, and/or portions, these elements, components, regions, layers, and/or portions shall not be limited by these terms. These terms are utilized only to distinguish one element, component, region, layer, or portion from another element, component, region, layer, or portion. Thus, without departing from the teachings of the present disclosure, a first element, component, region, layer, or portion discussed below may be represented as a second element, component, region, layer, or portion.

It should be appreciated that when one element is considered to be “connected” to another element, the element may be directly connected to the another element or connected to the another element through an intermediate element. In addition, the “connection” in the following embodiments should be interpreted as “electrical connection”, “communication connection”, and the like, if there exists an electrical signal or data transmission between the connected objects.

It should be appreciated that “an”, “one” and “the/said” in singular form may also include plural form unless the context clearly indicates another manner. It should also be appreciated that the term “include/comprise” or “have”, etc., specifies the presence of the stated features, entireties, steps, operations, components, portions or combinations thereof, but does not exclude the possibility of existing or adding one or more other features, entireties, steps, operations, components, portions or combinations thereof. Moreover, the term “and/or” includes any and all combinations of the related items listed herein.

The non-volatile memories may include, for example, a flash memory (FLASH), a Resistive Random Access Memory (RRAM), a Phase-Change Random Access Memory (PCRAM), and the like. The volatile memories may include, for example, a Static Random-Access Memory (SRAM) and a Dynamic Random Access Memory (DRAM). Non-Volatile Processing-In-Memory (NVPIM) refers to processing-in-memory based on a non-volatile memory. Compared to processing-in-memory based on a volatile memory, the NVPIM can retain data when powered off, thereby effectively reducing the power consumption required for data backup and data restoration.

At present, in the emerging non-volatile memories, the RRAM has received wide attention due to the advantages of multi-bit storage, high scalability, low power consumption, and compatibility with advanced CMOS processes.

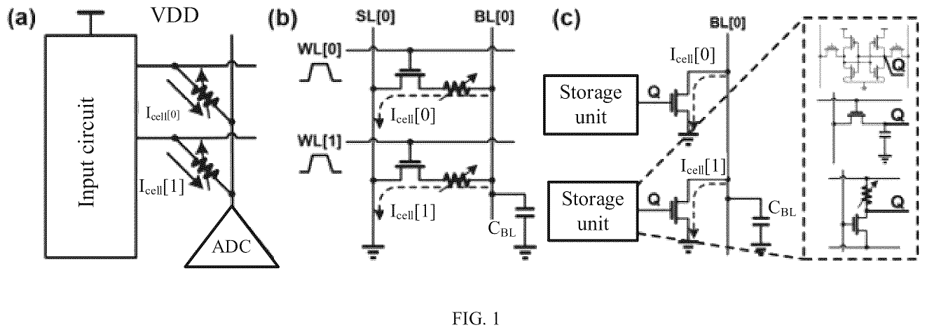

For example, in an existing RRAM-based non-volatile processing-in-memory (NVPIM) method, referring to diagram (a) in FIG. 1, a read current may be accumulated in a storage array according to Kirchhoff's law, and is read through an Analog-to-Digital Converter (ADC). However, such approach may face multiple challenges as follows: 1) during the computing, direct current (DC) paths existing in the RRAM and the read circuit may have significant energy consumption and tend to weaken the energy efficiency advantage of the PIM; (2) an on-off ratio of the RRAM is limited, and the IR-drop on the metal line caused by a large accumulated current may tend to cause nonlinearity and reduce accuracy of operation; 3) a peripheral circuit may easily occupy large area and large power consumption.

For example, in another existing RRAM-based non-volatile processing-in-memory (NVPIM) method, referring to the diagram (b) in FIG. 1, the basic principle of the method is still current summation. However, the discharge of the summation current results from a parasitic capacitance (C_{BL}) of the bit line (BL) rather than directly from the power supply voltage (VDD). In such a manner, a processing-in-memory result is obtained by quantizing the voltage on the bit line, so that a better energy efficiency can be provided by eliminating the DC path during the computing. However, such manner still has significant limitations: 1) to avoid read interference of the RRAM, the maximum voltage on the bit line is limited; 2) the parasitic capacitance of the bit line is insufficient to implement highly parallel discharge, and it is easy to deteriorate further due to the voltage swing limit on the bit line; 3) the discharge current flowing through the RRAM is directly proportional to the voltage on the bit line, which inherently introduces the nonlinearity problem. Although there are methods to alleviate such a nonlinearity problem, the nonlinearity problem may inevitably lead to costs in terms of area and power consumption.

In order to solve the above problems, the applicant has found an alternative method in which the discharge is performed through a transistor, for example, as shown in the diagram (c) of FIG. 1. The method decouples the RRAM and the discharge path, so that the risk of read interference can be eliminated. In addition, the discharge current may be controlled by a gate voltage of the transistor, so that the operation may be performed in a sub-threshold region of the transistor, which can significantly reduce the discharge current. In addition, the switching ratio of the unit may be enhanced by using a sub-threshold swing (SS) of the transistor. Further, based on a characteristic of the transistor operating in a saturation region, a voltage drop on a bit line has little effect on the discharge current. However, a transistor mismatch due to process fluctuations may adversely affect the accuracy of the processing-in-memory, especially when the transistor operates in the sub-threshold region. A voltage at a storage node (denoted as “Q”) of a storage unit consisting of the SRAM and the DRAM may be directly applied to a gate terminal of the discharge transistor. However, in addition to the volatile characteristic, the significant limitations of these designs do not eliminate the effect of the transistor mismatch. However, for the storage unit consisting of a non-volatile memory, such as the RRAM, information is stored in the form of resistance. Accordingly, the information needs to be first converted into a voltage form, so that a read voltage is applied to the storage unit, and then is divided by the transistor and the RRAM to establish a stable Q-point voltage. A significant disadvantage of such a method is the lack of a medium for preserving the Q-point voltage. As a result, once the read voltage applied across both ends of the storage unit is removed, the established Q-point voltage is lost. Accordingly, in order to implement the capacitor on the bit line discharging through the transistor, a DC path is still required, which may weaken the energy efficiency advantage of such a method. However, such a method can use the non-volatile property and multi-bit storage capability of the RRAM to allow fine tuning of the RRAM to compensate for the mismatch of the discharge transistor.

Based on this, in the embodiments of the present disclosure, a storage module, a storage array, a storage apparatus, and a processing-in-memory programming method are provided, which can not only have advantages of non-volatile, high on-off ratio, extremely low turn-on current, DC path elimination during the computing, and compensation for mismatch of the discharge transistor, but also effectively improve parallelism, linearity, and energy efficiency of the processing-in-memory.

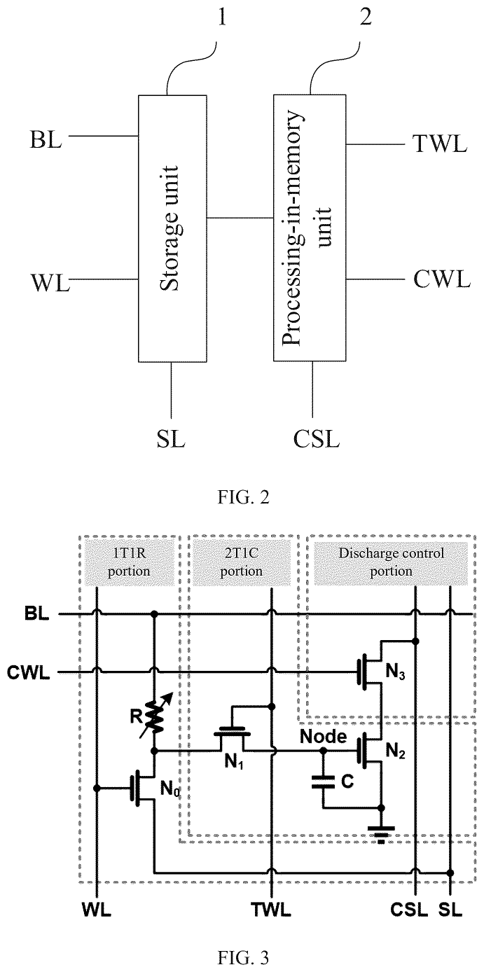

In some embodiments of the present disclosure, as shown in FIG. 2, a storage module HRC is provided, including a storage unit 1 and a processing-in-memory unit 2.

The storage unit 1 is configured to connect the word line WL, the bit line BL, and the source line SL, and is configured to perform data programming, data reading, or data deleting based on the word line WL, the bit line BL, and the source line SL in a storage mode.

The processing-in-memory unit 2 is connected to the storage unit 1, and is configured to: connect the timing word line TWL, the computing word line CWL, and the computing source line CSL; acquire stored data of the storage unit 1 based on the bit line BL and the timing word line TWL in a first phase of the processing-in-memory mode; and perform the processing-in-memory based on the computing word line CWL and the computing source line CSL in a second phase of the processing-in-memory mode.

For example, the processing-in-memory includes but is not limited to a Multiply-Accumulate (MAC) operation.

In some embodiments of the present disclosure, as shown in FIG. 3, the storage unit 1 includes a first transistor N₀ and a resistive random access memory R (such as a 1T1R portion in FIG. 3). The gate of the first transistor N₀ is connected to a word line WL. A first electrode of the first transistor N₀ is connected to a source line SL. A second electrode of the first transistor N₀ is connected to a first terminal of the resistive random access memory R. A second terminal of the resistive random access memory R is connected to a bit line BL.

In some embodiments of the present disclosure, as shown in FIG. 3, the processing-in-memory unit may include a second transistor N₁, a third transistor N₂, a capacitor C (such as a 2T1C portion in FIG. 3), and a fourth transistor N₃ (such as a discharge control portion in FIG. 3). The gate of the second transistor N₁ is connected to the timing word line TWL. The first electrode of the second transistor N₁ is connected to the storage unit 1, for example, a first terminal of the resistive random access memory R in the storage unit 1. The second electrode of the second transistor N₁, the gate of the third transistor N₂, and the first electrode of the capacitor C are connected to form a restoration node. The first electrode of the third transistor N₂ is connected to the second electrode of the capacitor C and is connected to a ground voltage terminal. The second electrode of the third transistor N₂ is connected to the first electrode of the fourth transistor N₃. The gate of the fourth transistor N₃ is connected to the computing word line CWL. The second electrode of the fourth transistor N₃ is connected to the computing source line CSL.

With reference to FIG. 3, It should be appreciated that the second transistor N₁, the third transistor N₂, the capacitor C, and the fourth transistor N₃ in the processing-in-memory unit may be correspondingly divided into a 2T1C portion and a discharge control portion according to functions thereof, as shown in FIG. 3. The second transistor N₁, the third transistor N₂, and the capacitor C form the 2T1C portion, and the fourth transistor N₃ forms the discharge control portion.

It should be noted that the above-mentioned storage module HRC has two operating modes: a storage mode and a processing-in-memory mode. The processing-in-memory mode may be divided into a first phase (e.g., a restoration phase “RESTORE”) and a second phase (e.g., a discharge phase “DISCHARGE”).

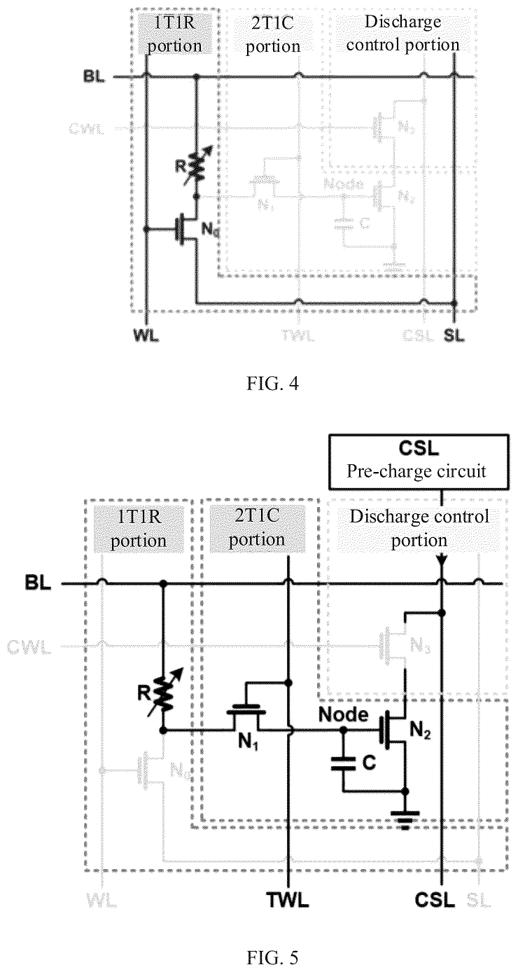

Referring to FIG. 4, the storage unit 1 (e.g., the 1T1R portion in FIG. 3) is activated in the storage mode. The data programming (e.g., “SET”), data reading (e.g., “READ”), or data deleting (e.g., “RESET”) may be performed on the resistive random access memory R by driving the word line WL, the bit line BL, and the source line SL. For the drive control of the word line WL, the bit line BL, and the source line SL, reference can be made to the drive of the resistive random access memory R in the related art, which is not limited by the embodiments of the present disclosure.

Optionally, in the storage mode, the computing word line CWL, the timing word line TWL, and the computing source line CSL are all connected to the ground voltage terminal.

Referring to FIG. 5, stored data of the storage unit 1 is acquired based on the bit line BL and the timing word line TWL in the first phase of the processing-in-memory mode (e.g., a restoration phase “RESTORE”). Specifically, the data stored in the resistive random access memory R may be converted into charges on the capacitor C.

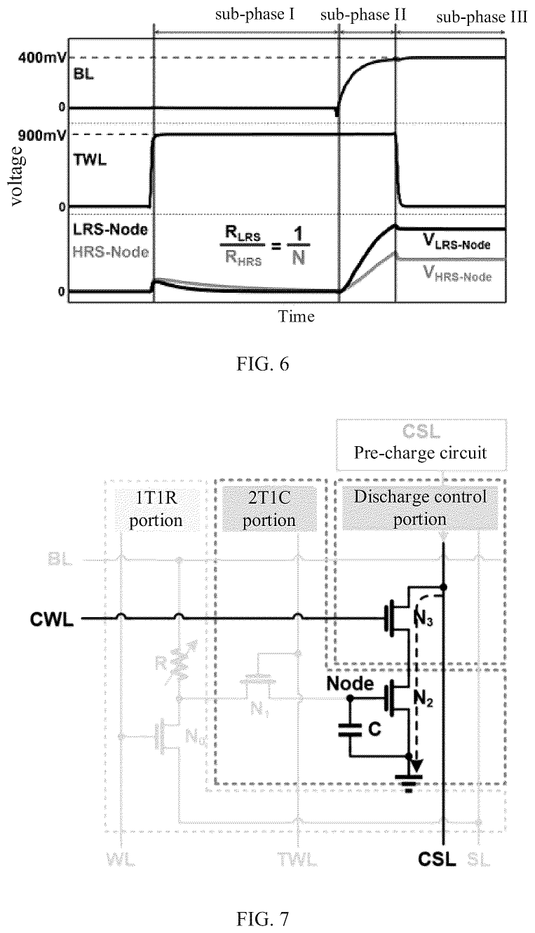

For example, the first phase of the processing-in-memory mode includes three sub-phases, such as a sub-phase I, a sub-phase II, and a sub-phase III shown in FIG. 6.

In the sub-phase I, the voltage on the timing word line TWL is pulled up to the power supply voltage VDD (e.g., a high-level voltage), and the bit line BL is connected to the ground voltage terminal to clear residual charges on the capacitor C.

In the sub-phase II, the bit line BL is charged to a preset voltage, and the timing word line TWL is maintained at the power supply voltage VDD. The second transistor N₁ is activated, the resistive random access memory R and the capacitor C are conductive, that is, the restoration node is allowed to be charged through the RC path, to improve efficiency based on the RC delay mechanism. In this case, a charging rate of the restoration node may change significantly according to different resistance values of the resistive random access memory R.

Optionally, the preset voltage is not greater than 400 mV, to guarantee that the third transistor N₂ can operate in the sub-threshold region, and the read interference to the resistive random access memory R is avoided.

In the sub-phase III, the voltage on the timing word line TWL is pulled down to cut off the above-mentioned RC path. In this case, the data stored in the resistive random access memory R is successfully converted into the charges on the capacitor C, and the second phase of the processing-in-memory mode (e.g., the discharge phase “DISCHARGE”) may be performed in sequence.

Optionally, in the sub-phase III, the voltage on the bit line BL is maintained at the preset voltage, which is beneficial to ensuring that the voltage at the restoration node can be maintained for a longer period of time.

In an example, referring to FIG. 6, the on-off ratio of the resistive random access memory R is N, that is, a low-resistance state (LRS) resistance value of the resistive random access memory R is 1/N of a high-resistance state (HRS) resistance value of the resistive random access memory R. Correspondingly, there may exist a certain difference between a voltage V_{LRS-Node} of the restoration node when the resistive random access memory R is in the LRS and a voltage V_{HRS-Node} of the restoration node when the resistive random access memory R is in the HRS at the end of the sub-phase III, i.e., at the end of the first phase of the processing-in-memory mode.

In the embodiments of the present disclosure, the ratio of the resistance value of the resistive random access memory R in the LRS to the resistance value of the resistive random access memory R in the HRS is only used for illustration purposes. At the end of the first phase of the processing-in-memory mode, the voltage at the restoration node may be significantly different due to the matching difference data stored in the resistive random access memory R, which does not serve as a related limitation on the embodiments of the present disclosure.

In some examples, as shown in FIG. 5, the computing source line CSL is further connected to a CSL pre-charge circuit, so that the computing source line CSL can be charged through the CSL pre-charge circuit in the first phase of the processing-in-memory mode.

In the second phase of the processing-in-memory mode (e.g., the discharge phase “DISCHARGE”), referring to FIG. 7, the processing-in-memory is performed based on the computing word line CWL and the computing source line CSL. Specifically, after the fourth transistor N₃ is controlled to be turned on through the computing word line CWL, the computing source line CSL may be discharged through a cascaded structure of the third transistor N₂ and the fourth transistor N₃.

In the embodiments of the present disclosure, the following three key functions can be implemented based on the fourth transistor N₃.

1) As an input terminal of the processing-in-memory, the fourth transistor N₃ allows different pulse widths proportional to an input value to be applied, in order to change discharge time, so that a multiplication of multiple bits by one bit can be implemented in one storage module HRC.

2) By reasonably selecting the pulse voltage for the computing word line CWL, the risk of current degradation of the computing source line CSL during the discharge can be minimized, which is beneficial to ensuring that the processing-in-memory of the storage module HRC has a higher linearity. For example, when the pulse voltage of the computing word line CWL is selected as V_{CWL}=500 mV, the current when the voltage V_{CSL} of the computing source line CSL drops to 0.2V due to discharge is 3.5% lower than the current when the voltage V_{CSL} of the computing source line CSL drops to 0.9V due to discharge.

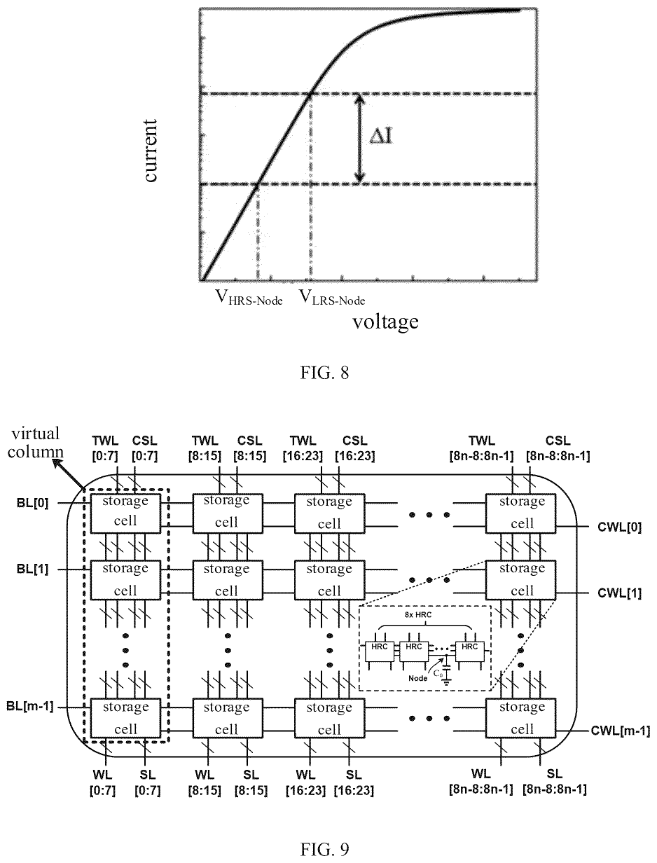

3) The fourth transistor N₃ can shield the coupling effect from the computing source line CSL to the restoration node. For example, under an action of the sub-threshold swing (SS) of the third transistor N₂, a voltage difference on the restoration node, that is, a difference between the voltage V_{HRS-Node} and the voltage V_{LRS-Node}, may be correspondingly converted into a difference which is greater than 10×N times the discharge current difference ΔI in the second phase of the processing-in-memory mode, thereby effectively amplifying the on-off ratio (N) of the storage unit, as shown in FIG. 8.

In addition, the storage module HRC provided in the embodiments of the present disclosure can suppress an amplitude of the discharge current to be less than 100nA, which makes it easier to implement high parallelism of the processing-in-memory. Further, in the storage module HRC provided in the embodiments of the present disclosure, the parasitic capacitance of the computing source line CSL is sufficient to implement the highly parallel discharge, and can even be accumulated in a process of multiple parallel activations of the computing word line CWL, thereby further improving the energy efficiency.

In the embodiment of the present disclosure, the storage module includes the storage unit 1 and the processing-in-memory unit 2. The storage unit 1 is configured to be connected to the word line WL, the bit line BL, and the source line SL, to perform the data programming, data reading, or data deleting based on the word line WL, the bit line BL, and the source line SL in the storage mode. The processing-in-memory unit 2 is configured to be connected to the storage unit 1, the timing word line TWL, the computing word line CWL, and the computing source line CSL, to acquire the stored data of the storage unit 1 based on the bit line BL and the timing word line TWL in the first phase of the processing-in-memory mode, and perform the processing-in-memory based on the computing word line CWL and the computing source line CSL in the second phase of the processing-in-memory mode. In the embodiment of the present disclosure, it is easy to decouple the operating paths of the storage module HRC in the storage mode and the processing-in-memory mode, which is convenient to effectively improve the parallelism, linearity, and energy efficiency of the processing-in-memory while ensuring that the storage module HRC has advantages of non-volatile, high on-off ratio, extremely low turn-on current, DC path elimination in the computing process, and compensation for discharge transistor mismatch.

In some embodiments of the present disclosure, as shown in FIG. 9, a storage array is further provided, including a plurality of storage cells arranged in an array. Each storage cell includes a plurality of storage modules HRC described in the above embodiments, which are arranged in rows in a first direction. The aforementioned technical advantages of the storage module are also shared by the storage array, which will not be repeated herein.

Optionally, a number of consecutive storage modules HRC in each row form one storage cell. In FIG. 9, as an example, eight storage modules HRC form one storage cell for illustration, which is not limited thereto, and the number of storage modules HRC in one storage cell may be other values. However, it should be appreciated that each storage module HRC in one storage cell stores data independently in the storage mode.

For example, as shown in FIG. 9, for an m ×n storage array, every eight storage modules HRC form one storage cell for illustration, there are m bit lines BL and m computing word lines CWL connected to each storage module HRC. There are 8n word lines WL, 8n timing word lines TWL, 8n source lines SL, and 8n computing source lines CSL connected to each storage module HRC.

In some embodiments of the present disclosure, restoration nodes of storage modules HRC in each storage cell are connected to each other and connected to one shared capacitor C₀, and the shared capacitor C₀ is configured to acquire stored data of a target storage module HRC in a corresponding storage cell in response to a processing-in-memory control instruction in the processing-in-memory mode (for example, the first phase of the processing-in-memory mode).

Optionally, the shared capacitor C₀ includes, but is not limited to, a metal-oxide-metal (MOM) capacitor.

In the embodiment of the present disclosure, each storage module HRC in any storage cell stores data independently. Accordingly, in the first phase of the processing-in-memory mode, the stored data in the target storage module may be restored to the shared capacitor C₀ by activating the timing word line connected to the target storage module. In such a manner, a storage density of the storage array is ensured and improved.

It should be noted that, in some embodiments of the present disclosure, storage cells are arranged in columns in a second direction, and the second direction intersects the first direction. At least one column of storage cells is a virtual column of storage cells. Each storage module HRC in the virtual column of storage cells stores pre-stored calibration data.

The pre-stored calibration data is not valid data for the processing-in-memory, and may be subtracted from a processing-in-memory result of the storage array, to calibrate the processing-in-memory result of the storage array, thereby obtaining a better linearity.

Optionally, the virtual column of storage cells is located at the far left of the storage array, and may be the first column from the left. However, the virtual column of storage cells is not limited thereto, which may be, for example, the middle column or the rightmost column of the storage array.

Optionally, the resistive random access memory R of each storage module HRC in the virtual column of storage cells is configured in the HRS, so that a leakage current in the processing-in-memory mode can be effectively monitored.

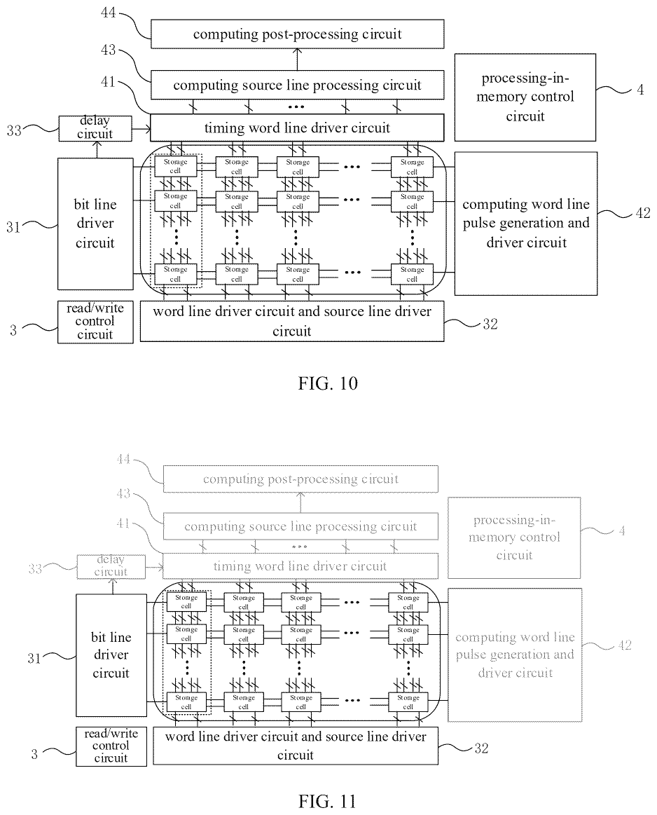

In some embodiments of the present disclosure, as shown in FIG. 10, a storage apparatus is provided, including the storage array mentioned in any of the above embodiments, a read/write control circuit 3, and a processing-in-memory control circuit 4. The aforementioned technical advantages of the storage array are also shared by the storage apparatus, which are not repeated herein.

The read/write control circuit 3 is connected to each storage cell in the storage array through a bit line driver circuit 31, a word line driver circuit, and a source line driver circuit 32. The read/write control circuit 3 is configured to transmit a storage control instruction to the bit line driver circuit 31, the word line driver circuit, and the source line driver circuit 32 respectively in the storage mode, to select a target storage module to perform data programming, data reading, or data deleting.

The processing-in-memory control circuit 4 is connected to each storage cell in the storage array through the timing word line driver circuit 41, the computing word line pulse generation and driver circuit 42, and the computing source line processing circuit 43. The processing-in-memory control circuit 4 is configured to: transmit a first processing-in-memory control instruction to the timing word line driver circuit 41 in the first phase of the processing-in-memory mode, to acquire stored data of a plurality of target storage modules; and transmit a second processing-in-memory control instruction to the computing word line pulse generation and driver circuit 42 and the computing source line processing circuit 43 in the second phase of the processing-in-memory mode, to perform the processing-in-memory on the stored data of the plurality of target storage modules.

Optionally, the word line driver circuit and source line driver circuit 32 are integrated into an integrated structure.

Optionally, the computing source line processing circuit 43 includes, but is not limited to, a circuit having a pre-charge function, a voltage comparison function, and a voltage quantization function.

In some embodiments of the present disclosure, as shown in FIG. 10, the storage apparatus further includes a delay circuit 33. The delay circuit 33 is connected to the bit line driver circuit 31 and the timing word line driver circuit 41, and is configured to control the charging time of the shared capacitor C₀ (i.e., charging time of the restoration node) in the processing-in-memory mode.

In some embodiments of the present disclosure, as shown in FIG. 10, the storage apparatus further includes a computing post-processing circuit 44. The computing post-processing circuit 44 is connected to the computing source line processing circuit 43, and is configured to perform post-processing on an operation structure of the processing-in-memory in the processing-in-memory mode, and output a post-processing result.

Optionally, the computing post-processing circuit 44 serving as an output circuit of the storage apparatus may perform the post-processing on the processing-in-memory result (e.g., an MAC result), for example, activation, bias addition, quantization to a low-precision representation, etc. A circuit structure of the computing post-processing circuit 44 is not specifically limited in the embodiments of the present disclosure, in order to ensure that a corresponding post-processing function can be implemented.

It should be noted that the above-mentioned storage apparatus has two operating modes: a storage mode and a processing-in-memory mode. The processing-in-memory mode may be divided into a first phase (e.g., a restoration phase “RESTORE”) and a second phase (e.g., a discharge phase “DISCHARGE”).

Referring to FIG. 11, in the storage mode, the read/write control circuit 3, the bit line driver circuit 31, the word line driver circuit and source line driver circuit 32 operate, while the delay circuit 33, the processing-in-memory control circuit 4, the timing word line driver circuit 41, the computing word line pulse generation and driver circuit 42, the computing source line processing circuit 43, and the computing post-processing circuit 44 are all in the off state. Accordingly, the read/write control circuit 3 may drive the corresponding bit line BL, word line WL, and source line SL respectively through the bit line driver circuit 31, the word line driver circuit and source line driver circuit 32, to select a target storage module from the storage array to perform the data programming (SET), the data reading (READ), or the data deleting (RESET).

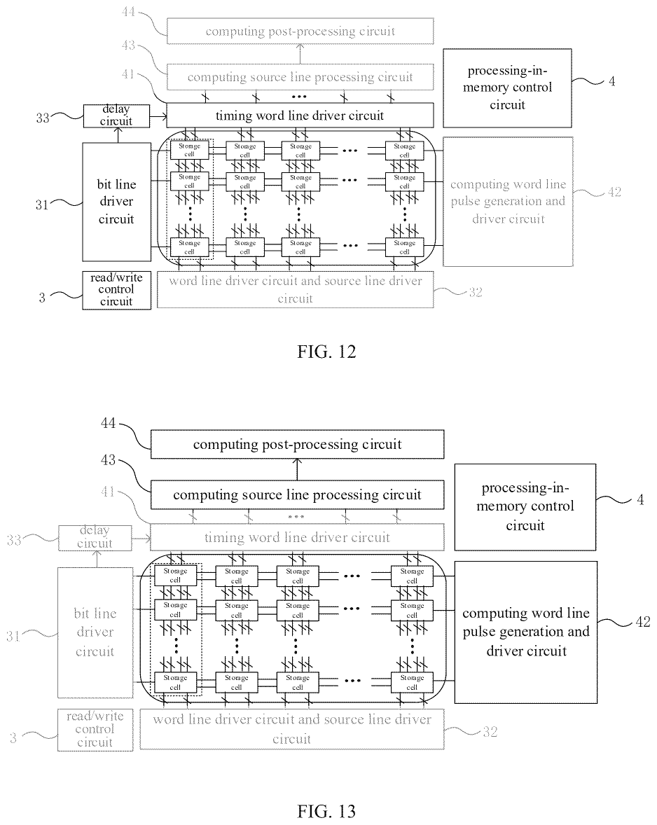

Referring to FIG. 12, in the first phase of the processing-in-memory mode, the read/write control circuit 3, the bit line driver circuit 31, the delay circuit 33, the processing-in-memory control circuit 4, and the timing word line driver circuit 41 operate, while the word line driver circuit and source line driver circuit 32, the computing word line pulse generation and driver circuit 42, the computing source line processing circuit 43, and the computing post-processing circuit 44 are all in the off state. Accordingly, the bit lines BL are activated in parallel through the bit line driver circuit 31, one timing word line TWL in each storage cell is activated in parallel through the timing word line driver circuit 41, and the charging time (i.e., the charging time of the restoration node) of the shared capacitor C₀ is controlled by the delay circuit 33, so that the stored data of the target storage module selected from each storage cell may be restored to the shared capacitor C₀.

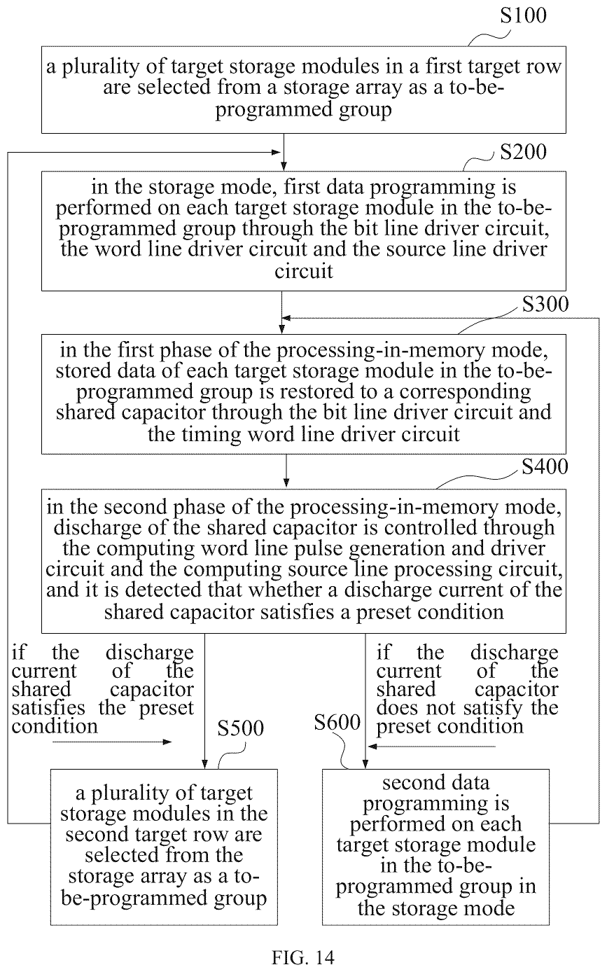

Referring to FIG. 13, in the second phase of the processing-in-memory mode, the processing-in-memory control circuit 4, the computing word line pulse generation and driver circuit 42, the computing source line processing circuit 43, and the computing post-processing circuit 44 operate, while the read/write control circuit 3, the bit line driver circuit 31, the word line driver circuit and source line driver circuit 32, the delay circuit 33, and the timing word line driver circuit 41 are all turned off. Accordingly, the computing word line pulse generation and driver circuit 42 receives the input value of the processing-in-memory, activates a quantity of computing word lines CWL in parallel, and generates a pulse signal with a pulse width directly proportional to the input value. The parasitic capacitance on the source line CSL discharges through the cascaded structure of the third transistor N₂ and the fourth transistor N₃ in the corresponding target storage module, so that the corresponding voltage can be converted to a digital value through the computing source line processing circuit 4, to serve as a processing-in-memory result (e.g., the MAC result). Optionally, the processing-in-memory result is output after being post-processed by the computing post-processing circuit 44.

In some embodiments of the present disclosure, a processing-in-memory programming method is provided, which is applied to the storage apparatus in any of the above embodiments. The technical advantages of the aforementioned storage apparatus are also shared by the processing-in-memory programming method, which are not repeated herein.

Referring to FIG. 14, the processing-in-memory programming method may include the following steps S100 to S600.

S100: a plurality of target storage modules in a first target row are selected from a storage array as a to-be-programmed group.

For example, for a storage array consisting of m×n storage cells, if i serves as a row number and numbering starts from 0, the first target row refers to a row of storage cells corresponding to i=0. Accordingly, step S100 may include: the storage array is initialized, so that i=0 (that is, programming starts from line 0).

For example, when the i-th row storage cell is programmed, the to-be-programmed group is a set of to-be-programmed storage modules HRC in the i-th row. In addition, each storage cell has only one to-be-programmed storage module HRC as a target storage module.

S200: in the storage mode, first data programming is performed on each target storage module in the to-be-programmed group through the bit line driver circuit, the word line driver circuit and the source line driver circuit.

The first data programming may refer to performing coarse tuning on a resistance value of the resistive random access memory R in the target storage module, with the purpose of facilitating a rapid convergence of the subsequent discharge current when the subsequent discharge current meets a preset condition. In addition, the operation of the first data programming may be implemented in combination with the operation of the storage apparatus in the storage mode in the aforementioned embodiments, and details are not described herein again.

S300: in the first phase of the processing-in-memory mode, stored data of each target storage module in the to-be-programmed group is restored to a corresponding shared capacitor through the bit line driver circuit and the timing word line driver circuit.

The restoration operation of the stored data in each target storage module can be implemented in combination with the operation of the storage apparatus in the first phase of the processing-in-memory mode in the aforementioned some embodiments, and details are not described herein again.

S400: in the second phase of the processing-in-memory mode, discharge of each shared capacitor is controlled through the computing word line pulse generation and driver circuit and the computing source line processing circuit, and it is detected whether a discharge current of each shared capacitor satisfies a preset condition.

The discharge operation of each shared capacitor may be implemented in combination with the operation of the storage apparatus in the second phase of the processing-in-memory mode in the aforementioned some embodiments, and details are not described herein again.

For example, the preset condition may be set by matching an error range allowed by the discharge current.

Accordingly, the programming method may further include the following steps S500 and S600.

S500: in response to the discharge current of the shared capacitor satisfying the preset condition, a plurality of target storage modules in the second target row are selected from the storage array as a to-be-programmed group.

In other words, if the discharge current of the shared capacitor satisfies the preset condition, the storage cells in the i-th row are programmed successfully, and the storage cells in the (i+1)-th row may be programmed.

S600: in response to that the discharge current of the shared capacitor does not satisfy the preset condition, second data programming is performed on each target storage module in the to-be-programmed group in the storage mode, and the stored data of each target storage module in the to-be-programmed group is restored to a corresponding shared capacitor in the processing-in-memory mode, to redetect that whether the discharge current of the shared capacitor satisfies the preset condition.

In other words, if the discharge current of the shared capacitor does not satisfy the preset condition, the second data programming needs to be performed on the storage cells in the i-th row. In addition, after the second data programming is performed, the process may return to step S300 and step S400. In such a manner, through the loop operation of the second data programming, it can be ensured that storage cells in any row are successfully programmed.

For example, a programming precision of the second data programming is higher than that of the first data programming. That is, the second data programming may refer to performing fine tuning on the resistance value of the resistive random access memory R in the target storage module, which may be specifically implemented by adjusting parameters such as an amplitude, a width, etc., of a programming pulse.

In the embodiments of the present disclosure, data programming is performed on the selected to-be-programmed group in the storage mode, and processing-in-memory simulation is performed in combination with the processing-in-memory mode, which can guarantee that the discharge current of the successfully programmed storage cell can satisfy the preset condition (that is, within an error range), thereby effectively compensating for mismatch of a discharge transistor in the storage module, in order to improve the linearity and computing accuracy of the processing-in-memory.

Any combination of the technical features of the aforementioned embodiments may be performed. To make the description brief, all possible combinations of the technical features of the aforementioned embodiments are not described. However, as long as there is no contradiction between the combinations of the technical features, the combinations of the technical features should be considered as the scope of the present disclosure.

The aforementioned embodiments represent only several implementation manners of the present disclosure, and descriptions thereof are relatively specific and detailed, but may not be construed as a limitation on the scope of the present disclosure. It should be noted that a person of ordinary skill in the art may make some transformations and improvements without departing from the concept of the present disclosure, which all fall within the protection scope of the present disclosure. Therefore, the scope of protection of the present disclosure shall be subject to the appended claims.

What is claimed is:

1. A storage array, comprising a plurality of storage cells arranged in an array, each storage cell comprising a plurality of storage modules arranged in rows in a first direction;
wherein each storage module comprises:
a storage unit, configured to connect a word line, a bit line, and a source line, and configured to perform data programming, data reading, or data deleting based on the word line, the bit line, and the source line in a storage mode;
a processing-in-memory unit, connected to the storage unit, and configured to: connect a timing word line, a computing word line, and a computing source line; acquire stored data of the storage unit based on the bit line and the timing word line in a first phase of a processing-in-memory mode; and perform processing-in-memory based on the computing word line and the computing source line in a second phase of the processing-in-memory mode;
wherein the processing-in-memory unit comprises a second transistor, a third transistor, a capacitor, and a fourth transistor; a gate of the second transistor is connected to the timing word line; a first electrode of the second transistor is connected to the storage unit; a second electrode of the second transistor, a gate of the third transistor, and a first electrode of the capacitor are connected to form a restoration node; a first electrode of the third transistor is connected to a second electrode of the capacitor and is connected to a ground voltage terminal; a second electrode of the third transistor is connected to a first electrode of the fourth transistor, a gate of the fourth transistor is connected to the computing word line, a second electrode of the fourth transistor is connected to the computing source line;
wherein restoration nodes of the plurality of storage modules in each storage cell are connected to each other and connected to a shared capacitor, the shared capacitor is configured to acquire stored data of a target storage module in a corresponding storage cell in response to a processing-in-memory control instruction in the processing-in-memory mode.

2. The storage array according to claim 1, wherein the plurality of storage cells are arranged in columns in a second direction, the second direction intersects the first direction, at least one column of storage cells is a virtual column of storage cells, each storage module in the virtual column of storage cells stores pre-stored calibration data.

3. The storage array according to claim 1, wherein the storage unit comprises a first transistor and a resistive random access memory, a gate of the first transistor is connected to the word line, a first electrode of the first transistor is connected to the source line, a second electrode of the first transistor is connected to a first terminal of the resistive random access memory, and a second terminal of the resistive random access memory is connected to the bit line.

4. A storage apparatus, comprising:
the storage array of claim 1;
a read/write control circuit, connected to each storage cell in the storage array through a bit line driver circuit, a word line driver circuit and a source line driver circuit, and configured to transmit a storage control instruction to the bit line driver circuit, the word line driver circuit and the source line driver circuit respectively in a storage mode, to select the target storage module to perform the data programming, the data reading, or the data deleting; and
a processing-in-memory control circuit, connected to each storage cell in the storage array through a timing word line driver circuit, a computing word line pulse generation and driver circuit, and a computing source line processing circuit, and configured to: transmit a first processing-in-memory control instruction to the timing word line driver circuit in the first phase of the processing-in-memory mode, to acquire stored data of a plurality of target storage modules; and transmit a second processing-in-memory control instruction to the computing word line pulse generation and driver circuit and the computing source line processing circuit in the second phase of the processing-in-memory mode, to perform the processing-in-memory on the stored data of the plurality of target storage modules.

5. The storage apparatus according to claim 4, further comprising:
a delay circuit, connected to the bit line driver circuit and the timing word line driver circuit, and configured to control charging time of the shared capacitor in the processing-in-memory mode.

6. The storage apparatus according to claim 5, further comprising:
a computing post-processing circuit, connected to the computing source line processing circuit, and configured to perform post-processing on an operation structure of the processing-in-memory in the processing-in-memory mode and output a post-processing result.

7. A processing-in-memory programming method, applied to the storage apparatus of claim 4, the programming method comprising:
selecting a plurality of target storage modules in a first target row from the storage array as a to-be-programmed group;
in a storage mode, performing first data programming on each of the plurality of target storage modules in the to-be-programmed group through the bit line driver circuit, the word line driver circuit and the source line driver circuit;
in a first phase of a processing-in-memory mode, restoring stored data of each of the plurality of target storage modules in the to-be-programmed group to a corresponding shared capacitor of each target storage module through the bit line driver circuit and the timing word line driver circuit;
in a second phase of the processing-in-memory mode, controlling discharge of the corresponding shared capacitor of each target storage module through the computing word line pulse generation and driver circuit and the computing source line processing circuit, and detecting whether a discharge current of the corresponding shared capacitor of each target storage module satisfies a preset condition;
in response to the discharge current of the corresponding shared capacitor of each target storage module satisfying the preset condition, selecting a plurality of target storage modules in a second target row from the storage array as a to-be-programmed group; or
in response to that a discharge current of a corresponding shared capacitor of a target storage module in the plurality of target storage modules does not satisfy the preset condition, performing second data programming on each target storage module in the to-be-programmed group in the storage mode, and restoring stored data of each target storage module in the to-be-programmed group to a corresponding shared capacitor of each target storage module in the processing-in-memory mode, to redetect whether the discharge current of the corresponding shared capacitor of each target storage module satisfies the preset condition.

8. The processing-in-memory programming method according to claim 7, wherein a programming precision of the second data programming is higher than that of the first data programming.
